(19) United States
(12) Patent Application Publication
(10) Pub. No.: US 2025/0298064 A1
(43) Pub. Date: Sep. 25, 2025

(54) SYSTEM INCLUDING MULTIFUNCTIONAL DIRECT CURRENT POWER QUALITY METER AND OPERATING METHOD THEREOF

(71) Applicant: DONGWOO ELECTRIC CORP., Pyeongtaek-si (KR)

(72) Inventors: Sun Woo Kim, Hwaseong-si (KR); Hong Jun CHAE, Hwaseong-si (KR); Yeo Hyuck YOON, Hwaseong-si (KR)

(73) Assignee: DONGWOO ELECTRIC CORP., Pyeongtaek-si (KR)

(21) Appl. No.: 19/067,360

(22) Filed: Feb. 28, 2025

(30) Foreign Application Priority Data
Feb. 29, 2024 (KR) 10-2024-0030020

(51) Int. Cl. G01R 19/25; G01R 19/22; H02J 7/00

(52) U.S. Cl. CPC G01R 19/2513; G01R 19/22; H02J 7/00712

(57) ABSTRACT

The present invention relates to a system including a multifunctional DC power quality (PQ) meter, and an operation method thereof, the system comprising: the PQ meter; and a manager terminal, in particular, wherein the PQ meter includes: a first signal generation circuit that includes a current transformer and a voltage transformer, which are connected to both ends of an alternate current (AC) wire disposed at one end of AC/DC power converter, and applies first signals in connection with AC current and AC voltage, respectively, from the current transformer and voltage transformer; a second signal generation circuit that is connected to a DC wire disposed at the other end of the AC/DC power converter and applies second signals in connection with DC voltage and DC current, respectively, from the DC wire; a communication circuit; and a control circuit that generates PQ data based on applied signal, when at least one among the first and second signals is applied, and then transports the PQ data to the manager terminal at a constant cycle.

### RELATED APPLICATIONS

This application claims the benefit of Korean patent application #10-2024-0030020 filed Feb. 29, 2024.

### FIELD OF THE INVENTION

The present invention relates to a direct current (DC) power quality (PQ) meter having alternate current (AC) PQ meter function, more particularly, to a system that identifies power quality of AC line and DC line and enables concurrent measurement, and in which a management mechanism through analysis of measured data is constructed.

### BACKGROUND OF THE INVENTION

Conventionally, as shown in FIG. 1, there is an AC PQ meter for measuring power quality (PQ) of alternate current (AC), wherein a pair of voltage transformer and current transformer is coupled in each of a positive electrode wire, a negative electrode wire and a neutral wire in a three-phase AC system to acquire AC signal, thereby determining AC PQ. However, no apparatus for measurement of DC PQ is present, therefore, it does not now bother with the power quality at DC side. Further, when analyzing the cause of a fire in an energy storage system (ESS), review on the PQ at DC side is not performed.

The concept for DC PQ meter is under discussion, however, according to the discussed concept, even when a DC PQ meter is developed, AC PQ meter and DC PQ meter entail a problem that these cannot perform synchronous sampling. Therefore, it is obvious that accuracy in system analysis is deteriorated.

Further, due to harmonic wave generated in AC/DC power converter of the system equipped with ESS, troubles often occur. In particular, as shown in FIG. 2, image harmonic wave flows into a grounded voltage transformer (GVT) in a system provided with the GVT, causing a problem of false operation of a protective relay. In regard to such problem, there is a difficulty in quantitative analysis.

Accordingly, in addition to the development of DC PQ meter including the function of AC PQ meter, it is also necessary to develop the functions of GVT grounding wire in an alternate current system to measure and analyze current.

Meanwhile, the matters described in the above background of art are introduced only to facilitate understanding of the background of the present invention, it should not be construed as recognizing that these matters correspond to the conventional art already known to those skilled in the art.

### SUMMARY OF THE INVENTION

### Technical Problem to be Solved

In order to solve the above problems, an object of the present invention is to provide a system comprising a DC PQ meter using various voltage and current sensors, wherein the DC PQ meter has a measuring function such as DC single-phase 2 wire way, DC single-phase 3 wire way (capable of measuring neutral current in a single-phase 3 wire way), etc. and, simultaneously, executes sampling (synchronous sampling) when treating DC and/or AC signal, in order to provide data not displayed in the existing measurement device; transports the data to an external apparatus (ex. server, smartphone, computer, etc.) to provide a result of analyzing the data; may measure and analyze the current of a grounded voltage transformer (GVT) grounding wire of an alternate current (AC) system that uses GVT; and, when outputting the measured data through a display, may set an output area on a screen.

Problems to be solved by the present application are not particularly limited to the object described above, and other objects not mentioned herein would be clearly understood from the following description by those skilled in the art.

### Technical Solution

With regard to the system comprising PQ meter according to various embodiments of the present application, the system includes the PQ meter and a manager terminal, wherein the PQ meter may include: a first signal generation circuit that includes a current transformer and a voltage transformer, which are connected to both ends of an alternate current (AC) wire disposed at one end of AC/DC power converter, and applies first signals in connection with AC current and AC voltage, respectively, from the current transformer and voltage transformer; a second signal generation circuit that is connected to a DC wire disposed at the other end of the AC/DC power converter and applies second signals in connection with DC voltage and DC current, respectively, from the DC wire; a communication circuit; and a control circuit that generates PQ data based on applied signal, when at least one among the first and second signals is applied, and then transports the PQ data to the manager terminal at a constant cycle, wherein the number of the current transformers and the number of the voltage transformers correspond to the number of phases on the AC wire, and the PQ data include at least one data among a relationship between voltage bandwidth and power quality, supply voltage deviation, ripple and high frequency noise, voltage rise and droop, voltage supply cut-off, rapid change in voltage, voltage surge and voltage imbalance.

According to an exemplary embodiment of the present application, the PQ meter includes a display, the control circuit identifies areas of the display, on which PQ data for AC and PQ data for DC are outputted, respectively; and, when PQ is not included in a standard range, outputs the PQ data on a matching area based on the PQ data through the display.

According to an exemplary embodiment of the present application, the first signal generation circuit includes: an AC voltage sensor; an AC current sensor; and a plurality of first analog front ends (AFEs) connected to the AC voltage sensor and the AC current sensor, respectively; the second signal generation circuit includes: a DC voltage sensor; a DC current sensor; and a plurality of second AFEs connected to the DC voltage sensor and the DC current sensor, respectively.

According to an exemplary embodiment of the present application, the PQ meter includes at least one analog-to-digital converter (ADC), wherein, when one ADC is used, it receives analog signals from the first AFE and the second AFE; and, when several ADCs are used, they receive analog signals from the first AFE and the second AFE, respectively.

According to an exemplary embodiment of the present application, the ADC is controlled by the control circuit or an external ADC control circuit.

According to an exemplary embodiment of the present application, wherein the first signal generation circuit applies the first signal from a grounding wire when the circuit is connected to the grounding wire of a grounded voltage transformer (GVT).

According to an exemplary embodiment of the present application, wherein the manager terminal includes: a processor; a memory; and a communication module, wherein the memory includes commands for the processor to execute the following steps, and the steps include: receiving the PQ data from the PQ meter; determining power supply based on the PQ data; and outputting alarm for supply limitation based on the determined result.

According to an exemplary embodiment of the present application, the system includes a storage apparatus, and the storage apparatus include: a first switch located on the DC wire; a charge wire, which is connected to a point between the AC/DC power converter and the first switch at one end of the charge wire on the DC wire, and includes a second switch; a battery connected to the other end of the charge wire to store power; a second communication circuit; and a second control circuit to control operation of the second switch, wherein the second signal generation circuit is connected between the AC/DC power converter and the above point, wherein the steps include: when a power quality (PQ) is determined to be less than a critical level in the case of determining the supply of power, transporting a control command to the storage apparatus to open the first switch while closing the second switch, so as to charge the battery; and when the PQ is not less than the critical level and is maintained this state over a predetermined time, transporting another control command to the storage apparatus to close the first switch while opening the second switch based on the PQ data, so as to apply the supply of power.

According to an exemplary embodiment of the present application, based on learning data including at least one among data for PQ change per time, data for wire replacement history, data for specification of power converter, data for specification of switch, and data for operational history of switch, the memory includes an artificial intelligence (AI) model that is trained to determine the number of switch operations, the expected time point at which PQ is changed to less than the critical level in regard to data for PQ, and the component causing deterioration in PQ among the power converter, wires and switches, and wherein the steps include: inputting the cumulative number of operations of each of the first switch and the second switch, and PQ data into the AI model in order to determine power supply; determining a first time point to operate the switch within a first time as a predetermined time, based on the output of AI model; and outputting alarm for the first time point when the first time point is determined.

According to an exemplary embodiment of the present application, the steps include: in the case of determining the first time point, when the first time point is determined, determining a second time point at which PQ is not less than the critical level within a second time as another predetermined time longer than the first time, based on the output of AI model; when the second time point is not determined, identifying at least one aged component among the AC/DC power converter, the DC wire, the AC wire, the first switch and the second switch data, based on the output of AI model; and when the aged component is identified, outputting a request for replacing the aged component and, when the aged component is not identified, outputting a request for entire inspection of power facilities.

### Effect of Invention

Other detailed matters of the present application are included in the detailed description and drawings.

### BRIEF DESCRIPTION OF THE DRAWINGS

FIG. 1 illustrates a method of installing the conventional AC PQ meter.

FIG. 2 is a circuit diagram showing a system in which the conventional GVT, and AC/DC power converter are included.

FIG. 3 is a block diagram showing the system according to an embodiment of the present invention.

FIG. 4 is a flow diagram illustrating the basic operation of a control circuit according to an embodiment of the present invention.

FIGS. 5 to 8 are block diagrams illustrating signal treatment according to an embodiment of the present invention.

FIGS. 9 and 10 show examples of set-up change to a display region in the display according to an embodiment of the present invention.

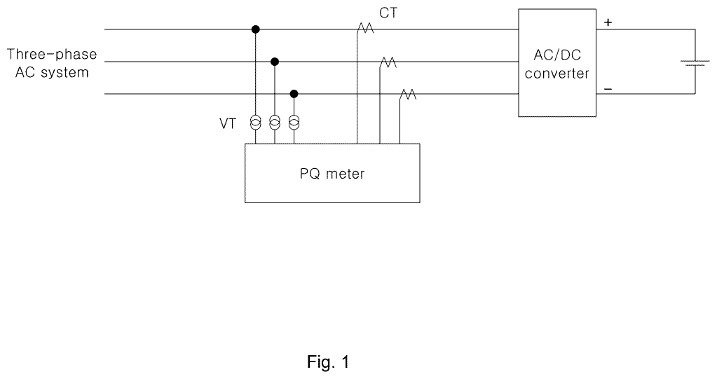

### DETAILED DESCRIPTION

Various embodiments will now be described with reference to the drawings. In this specification, various descriptions are provided to enhance the understanding of the present invention. However, it is evident that these embodiments can be implemented without such specific descriptions.

The terms “component,” “module,” “system,” and the like, as used in this specification, refer to computer-related entities, hardware, firmware, software, a combination of software and hardware, or software execution. For example, a component may be a process executed on a processor, a processor itself, an object, an execution thread, a program, and/or a computer, but is not limited thereto. For instance, both an application running on an electronic device and the electronic device itself can be considered components. One or more components may reside within a processor and/or execution thread. A component may be localized within a single computer, or it may be distributed across two or more computers. Additionally, these components may execute from various computer-readable media that contain different data structures. Components may also communicate through local and/or remote processing based on signals that include, for example, one or more data packets from a local system, a component interacting with another component in a distributed system, and/or data transmitted over a network such as the Internet to another system.

Furthermore, the term “or” is intended to signify an inclusive “or” rather than an exclusive “or.” That is, unless explicitly specified or clear from the context, the expression “X uses A or B” is intended to mean any of the following: X uses A, X uses B, or X uses both A and B. Additionally, the term “and/or,” as used in this specification, should be understood as encompassing any possible combinations of one or more of the listed items.

The terms “comprises” and/or “including,” as used herein, should be understood to indicate the presence of the corresponding features and/or elements. However, these terms should not be interpreted as excluding the presence or addition of one or more other features, elements, and/or their combinations. Also, unless otherwise specified or contextually clear that a singular form is intended, the singular form in this specification and the claims should generally be interpreted as meaning “one or more.”

Moreover, the phrase “at least one of A or B” should be understood to mean “including A only,” “including B only,” or “including a combination of both A and B.”

Those skilled in the art will further recognize that various exemplary logical blocks, configurations, modules, circuits, means, logic, and algorithm steps described in connection with the disclosed embodiments may be implemented in electronic hardware, computer software, or a combination of both. To explicitly illustrate the interchangeability of hardware and software, various exemplary components, blocks, configurations, means, logic, modules, circuits, and steps have been described in terms of their functionalities. Whether such functionalities are implemented as hardware or software depends on the specific application and design constraints imposed on the overall system. Skilled engineers can implement the described functionalities in different ways for each specific application. However, such implementation choices should not be interpreted as deviating from the scope of the present disclosure.

The descriptions of the presented embodiments are provided to enable those skilled in the art to utilize or implement the present disclosure. Various modifications to these embodiments will be apparent to those skilled in the art. The general principles defined herein can be applied to other embodiments without departing from the scope of the present disclosure. Therefore, the present disclosure is not limited to the described embodiments but should be construed in the broadest scope consistent with the principles and novel features disclosed herein.

In this specification, the terms “network function,” “artificial neural network,” and “neural network” may be used interchangeably.

The various embodiments described herein may be implemented, for example, using a computer or similar device by utilizing software, hardware, or a combination thereof in a computer-readable recording medium or storage medium.

In a hardware implementation, the embodiments described herein may be implemented using at least one of application-specific integrated circuits (ASICs), digital signal processors (DSPs), digital signal processing devices (DSPDs), programmable logic devices (PLDs), field-programmable gate arrays (FPGAs), processors, controllers, microcontrollers, microprocessors, or other electrical units for performing functions. In some cases, the embodiments described in this specification may be implemented directly in the processor of an electronic device.

The above drawings are provided as examples such that the idea of the present invention is sufficiently given to those skilled in the art.

Therefore, the present invention is duly not limited to the drawings proposed below but may be specified in other forms.

Further, like reference numerals denote like components throughout the specification.

Further, in order to aid understanding, it should be noted that the drawings are not necessarily proportional to scale but specific parts are enlarged or reduced in size.

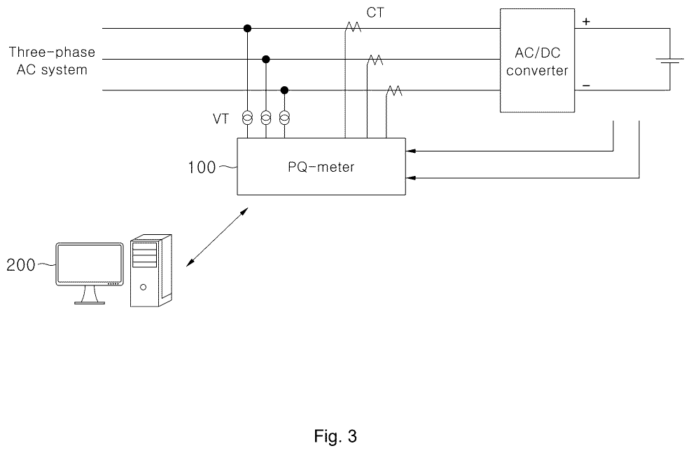

FIG. 3 is a block diagram showing the system according to an embodiment of the present invention.

As shown in FIG. 3, the system of the present invention includes a power quality (PQ) meter 100 and a manager terminal 200, wherein the manager terminal may include a variety of electronic devices such as a server, a mobile terminal, lap-top computer or desk-top computer of a user, and the like.

The PQ meter 100 includes a first signal generation circuit, a second signal generation circuit, a communication circuit and a control circuit 7.

The first signal generation circuit may include a current transformer and a voltage transformer, which are connected to both ends of an alternate current (AC) wire disposed at one end of an AC/DC power converter, wherein first signals in relation to AC and AC voltage are applied from the current transformer and the voltage transformer, respectively.

The number of the current transformers and the number of the voltage transformers, as shown in FIG. 3, correspond to the number of phases on the AC wire. Therefore, in the case where the AC wire is a three-phase AC wire, the number of the current transformers and the number of the voltage transformers may be each 3.

The second signal generation circuit may be connected to a direct current (DC) wire disposed at the other end of the AC/DC power converter, and apply second signals in relation to DC voltage and DC, respectively, from the DC wire.

At this time, the DC wire may be any one of DC single-phase 2 wire type or DC single-phase 3 wire type and, when the DC wire is the DC single-phase 3 wire type, the second signal generation circuit may measure current not only to a positive electrode wire and a negative electrode wire, but also to a neutral wire, so as to generate the second signals.

The communication circuit to transport wireless or wired signals to another device may include a function of executing communication with an external apparatus.

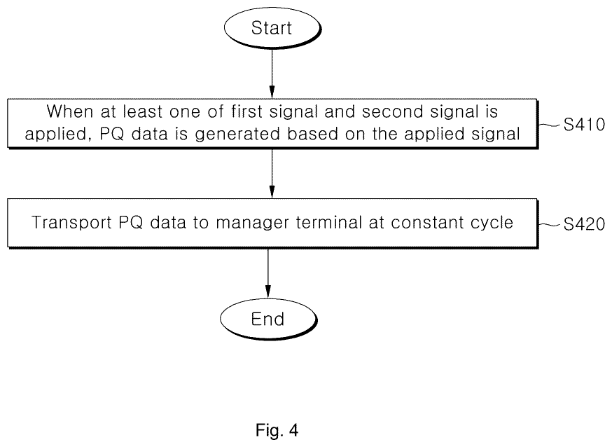

FIG. 4 is a flow diagram illustrating a basic operation of the control circuit 7 according to an embodiment of the present invention.

As shown in FIG. 4, the control circuit 7 may generate PQ data based on applied signal when at least one of the first signal and second signal is applied (S410), and the manager terminal 200 may transport the accumulated and generated PQ data at a constant cycle (S420).

PQ data may include at least one data among a relationship between voltage bandwidth and power quality, supply voltage deviation, ripple-high frequency noise, voltage rise and reduction, voltage supply cut- off, rapid change in voltage, voltage surge and voltage imbalance.

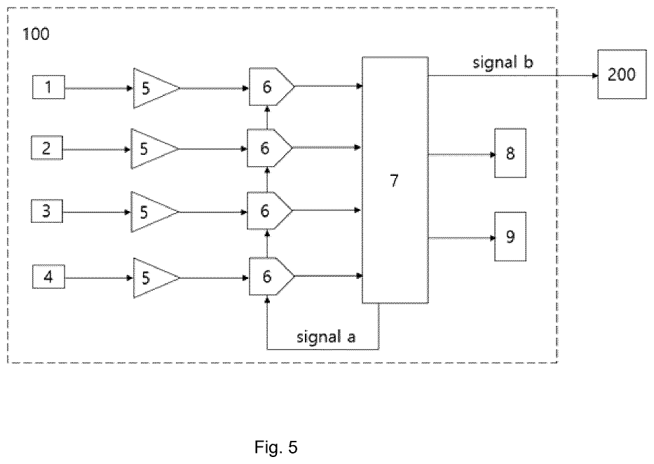

FIGS. 5 to 8 are block diagrams illustrating signal treatment according to an embodiment of the present invention.

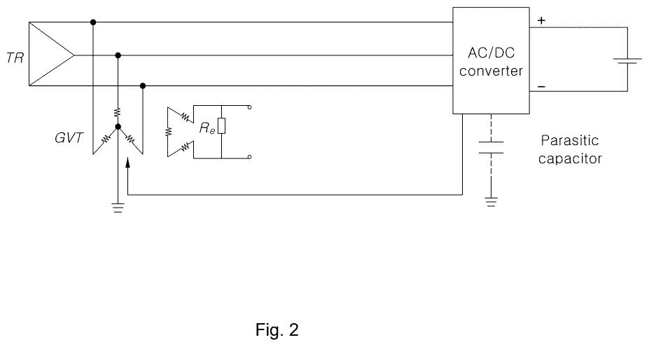

Specifically, as shown in FIG. 2, the first signal generation circuit may include an AC voltage sensor 3, an AC current sensor 4, and a plurality of analog front ends (AFE) 5 connected to the AC voltage sensor 3 and the AC current sensor 4, respectively.

Further, the second signal generation circuit may include a DC voltage sensor 1, a DC current sensor 2, and a plurality of AFEs 5 connected to the DC voltage sensor 1 and the DC current sensor 2, respectively.

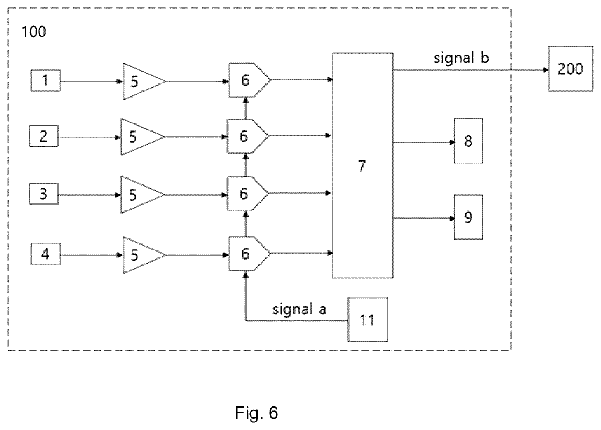

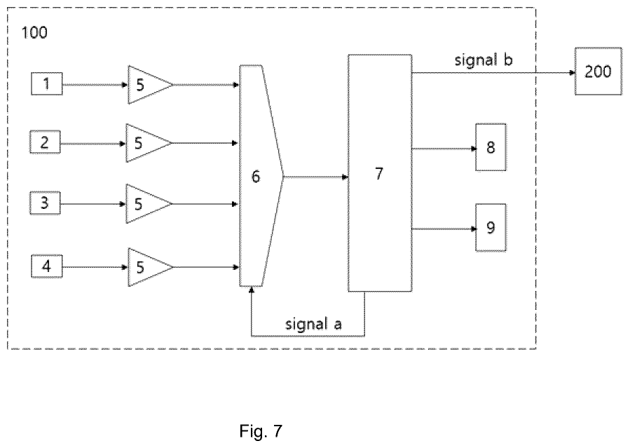

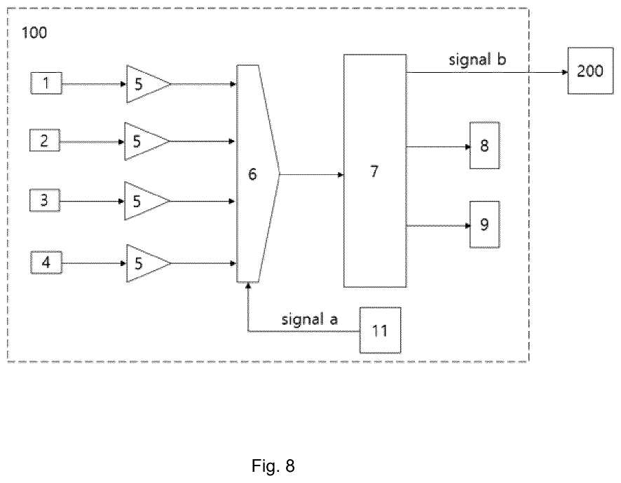

Accordingly, the PQ meter 100 includes at least one analog-to-digital converter (ADC) 6, wherein, when one ADC 6 is used as shown in FIGS. 7 and 8, the ADC receives analog signals from a plurality of AFEs 5 (a plurality of first AFEs, and a plurality of second AFEs); otherwise, when multiple ADCs 6 (equal to the number of total AFEs 5) are used as shown in FIGS. 5 and 6, each of the ADCs 6 may receive analog signal from each AFE 5.

PQ meter 100 includes ADC 6 and may perform synchronous sampling of the first and second signals.

Further, ADC 6 according to various embodiments of the present invention, as shown in FIGS. 5 and 7, may be controlled by receiving ADC control signal (signal a) from the control circuit 7, otherwise, as shown FIGS. 6 and 8, may be controlled by receiving ADC control signal (signal a) from an external ADC control circuit 11.

When measuring PQ of the AC wire and DC wire interconnected through AC/DC power converter by the PQ meter 100 of the present invention, simultaneously, more information may be obtained than obtaining limited information by measuring PQ of only any one of the AC wire and the DC wire. Further, if synchronous sampling is possible through ADC control, much more and useful information (ex. temporarily transient state) can be confirmed.

Specifically, in regard to implementing step S410, the control circuit 7 may execute synchronization of the first signal and second signal and generate PQ data based on the synchronized first and second signals, and may transport the generated PQ data (signal b: PQ data) to the manager terminal 200, as shown in FIGS. 5 to 8.

Meanwhile, although not shown in the figures, the first signal generation circuit according to various embodiments of the present invention applies first signals from a grounding wire when it is connected to the grounding wire of grounded voltage transformer (GVT) in an alternate current system using GVT, so that it may measure and analyze current of the GVT grounding wire of the alternate current system using GVT. Therefore, it is possible to conduct quantitative analysis of lots of troubles owing to harmonic wave generated in AC/DC power converter in the system provided with GVT as well as an energy storage system (ESS).

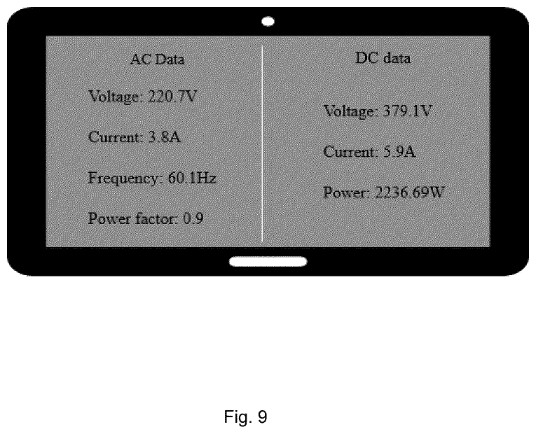

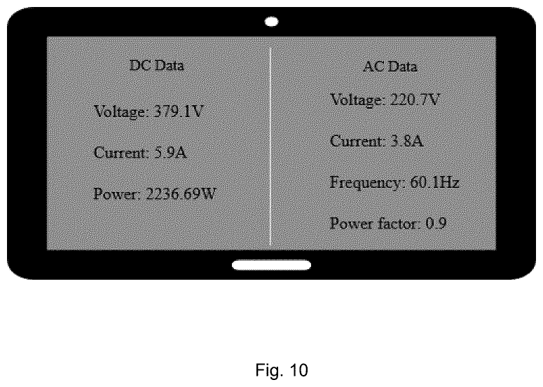

FIGS. 9 and 10 show examples of set-up change to the display region in the display according to an embodiment of the present invention.

Meanwhile, the PQ meter 100 according to various embodiments of the present invention, as shown in FIGS. 5 to 8, may include a data display device 8 and a display 9 that visualizes and outputs data according to the data display device 8, wherein the display 9 may include a variety of displays, in particular, a touch-screen display.

Therefore, the control circuit 7, as shown in FIGS. 9 and 10, may identify areas of the display 9, on which PQ data for AC and PQ data for DC are separately outputted based on the set-up and, if PQ is not within a standard range based on PQ data, may output PQ data on its matching area. Further, it is not limited to the above, the control circuit may update the generated PQ data and output the same all the time through the display 9.

At this time, the areas on which PQ data for AC and PQ data for DC are outputted may be crossed by a user through a set-up change of the data display device 8, as shown in FIGS. 9 and 10.

The manager terminal 200 in an embodiment of the present invention may include other components to execute computing environment of the manager terminal 200, and only a part of the components may configure the manager terminal 200.

The manager terminal 200 may include a processor, a memory and a communication module.

A processor may be composed of one or more cores and may include processors for data analysis and deep learning, such as the central processing unit (CPU) of the administrator terminal (200), the general-purpose graphics processing unit (GPGPU), and the tensor processing unit (TPU). The processor may read a computer program stored in memory to perform data processing for machine learning according to an embodiment of the present disclosure. Additionally, the processor may control the operation of the administrator terminal (200) and implement the overall operation of the system.

For example, the processor may typically control the overall operation of the administrator terminal (200). By processing signals, data, and information that are input or output through the components described above or by executing applications stored in memory, the processor may provide or process appropriate information or functions for the user.

Moreover, to execute applications stored in memory, the processor may control at least some of the components of the administrator terminal (200). Furthermore, for the execution of such applications, the processor may operate at least two or more of the components included in the administrator terminal (200) in combination.

According to an embodiment of the present disclosure, the processor may perform computations for neural network training. Specifically, the processor may carry out calculations for neural network training, such as processing input data for deep learning (DL), extracting features from input data, calculating errors, and updating the weights of the neural network using backpropagation. At least one of the CPU, GPGPU, and TPU of the processor may handle the training of network functions. For example, the CPU and GPGPU may work together to process network function training and data classification using network functions.

According to an embodiment of the present disclosure, the memory may store any type of information generated or determined by the processor and any type of information received by the network unit. The memory may include at least one type of storage medium such as flash memory type, hard disk type, multimedia card micro type, card-type memory (e.g., SD or XD memory), random access memory (RAM), static random access memory (SRAM), read-only memory (ROM), electrically erasable programmable read-only memory (EEPROM), programmable read-only memory (PROM), magnetic memory, magnetic disk, or optical disk. The administrator terminal (200) may also operate in connection with web storage that performs memory storage functions over the Internet. The descriptions of the memory provided above are merely exemplary and do not limit the scope of the present disclosure.

A communication module that transmits wireless or wired signals to other devices may perform communication with external devices. In particular, the communication module may include various communication chips such as a Wi-Fi chip, a Bluetooth chip, a wireless communication chip, an NFC chip, or a low-energy Bluetooth chip (BLE chip), or may be configured as a communication circuit that performs such functions.

Further, the manager terminal 200 may include a display, and the display may include a variety of displays, in particular, a touch-screen display.

Meanwhile, the memory may include commands for the processor to execute the following steps.

Specifically, in order to execute the steps, the manager terminal 200, as shown in FIGS. 5 to 8, may determine whether to supply power or not based on accumulated and received PQ data when PQ data is received from the PQ meter 100 and, according to the result of the determination, may output alarm for limiting the supply to ask stopping of power supply (or circuit interruption).

At this time, although not shown in the figures, the system may include a storage apparatus.

The storage apparatus may include a first switch, a second switch, a battery, a second communication circuit and a second control circuit 7.

The first switch is located on the DC wire, and a charge wire is connected to a point between the AC/DC power converter and the first switch at one end of the charge wire on the DC wire and may include the second switch.

The battery is connected to the other end of the charge wire to store power, the second communication circuit transporting wireless or wired signals to another apparatus include a function of executing communication with any external apparatus, and the second control circuit 7 may control operation of the second switch.

Therefore, the second signal generation circuit may be connected between the AC/DC power converter and the point described above.

According to the above configuration and steps, with regard to the determination of power supply, the manager terminal 200 may transport a control command to open the first switch and close the second switch to the storage apparatus when PQ is less than a critical level, so as to prevent the current from flowing to the DC wire with occurrence of quality deterioration, instead, may supply DC outputted from the AC/DC power converter to the battery, thereby charging the battery.

Subsequently, the manager terminal 200 may transport a control command to close the first switch and open the second switch to the storage apparatus, when PQ is not less than the critical level and maintained over a predetermined time based on the accumulated and received PQ data, thereby applying power supply.

According to one embodiment, the manage terminal 200 may identify occurrence of at least one transient current among non-continuous transient current and vibrational transient current, based on the accumulated and received PQ data.

At this time, if the occurrence of transient current is identified, the manager terminal 200 may identify one expected to have occurrence of transient current among AC wire and DC wire by comparing the synchronous first signal and the synchronous second signal based on the accumulated and received PQ data.

The manage terminal 200 may transport a control command to open all of the first switch and the second switch to the storage apparatus, if the identified wire is AC wire, thereby blocking the flow of current.

On the contrary, if the identified wire is DC wire, the manage terminal 200 may transport a control command to open the first switch while closing the second switch, so as to block the flow of current on DC wire while charging the battery.

According to one embodiment, when the occurrence of transient current is identified, the manager terminal 200 may determine the type of the identified transient current among non-continuous transient current and vibrational transient current.

Accordingly, the manager terminal 200 may receive weather data matching to the position data already registered for PQ meter 100 from a server of the weather center (such as the Meteorological Agency) when it was determined to generate the non-continuous transient current.

Based on the weather data, if a time zone including the present time point is identified as a time zone in which lightning occurs, otherwise, if lightning forecast matching thereto within a critical time period from the present time point is identified, the manager terminal 200 may transport a control command to open all of the first switch and the second switch to the storage apparatus during the time expected that the lightning according to the weather data occurs, thereby blocking the flow of current.

Further, the manager terminal 200 may output alarm for the occurrence of temporarily transient current due to the lightning.

Meanwhile, based on learning data including at least one among data for PQ change per time point, data for wire replacement history, data for specification of power converter, data for specification of switch, and data for operational history of switch, the memory may include an artificial intelligence (AI) model that is trained to determine the number of switch operations, the expected time point at which PQ is changed to less than the critical level in regard to data for PQ, and the components causing deterioration in PQ among the power converter, wires and switches. Herein, the data for specification may include information on basic specification for each apparatus (power converter, switch, etc.) such as item name, manufacturer, production date, load efficiency, maximum output, duration, working environment temperature, relative humidity, storage temperature, insulation resistance, voltage performance, materials, noise, weight, time point of use, etc., as well as the time point of use of currently used apparatus.

With regard to the steps according to the above embodiments, the manager terminal 200 may input the cumulative number of operations of each of the first switch and the second switch, and PQ data into the AI model, thereby acquiring output of the AI model.

Based on the output of AI model, the manager terminal 200 may determine a first time point to operate the switch within a first time as a predetermined time and, when the first time point is determined, may output alarm for the first time point to indicate a time point to block the flow of current in advance, thereby preventing the current with lack of PQ from being supplied.

At this time, with regard to the determination of first time point, when the first time point is determined, a second time point which is another predetermined time longer than the first time and at which PQ is not less than the critical level within the second time can be determined based on the output of AI model.

If the second time point is not determined, the manager terminal 200 may identify at least one aged component among the AC/DC converter, DC wire, AC wire, first switch and second switch, based on the output of AI model.

In this regard, if the aged component is identified, the manager terminal 200 may output a request for replacing the aged component. On the contrary, if any aged component is not identified, the manage terminal may output a request for entire inspection of power facilities, thereby proposing a solution for unsatisfactory PQ.

According to embodiments of the present invention, when receiving user command to select at least one replacement component as a new component for replacement, after outputting the request for replacing the aged component, the manager terminal 200 may update the data for specification of the replacement component based on the time point at which the replacement component was selected, and then, terminate the alarm output.

In this case, when new PQ data is received in a state that the user command for selecting the replacement component is not received yet, the manager terminal 20 may output alarm for danger occurrence.

Meanwhile, according to an embodiment, the output of AI model for the component causing PQ deterioration may be generated in a probability that each component affects the PQ deterioration, for this purpose, the learning data may include data for temperature and humidity per time.

Therefore, with regard to the determination of power supply, the manager terminal 200 may input the cumulative number of operations for each of the first switch and the second switch, PQ data and accumulated weather data into the AI model.

Accordingly, when receiving the user command for selecting the replacement component, the manager terminal 200 may identify whether the replacement component is identical to the identified aged component.

At this time, if the replacement component is different from the identified aged component, when a probability that the replacement component influences on the deterioration of PQ matching to the replacement component is less than a critical probability according to the output of AI model, the manager terminal 200 may receive weather data during a time period from the time point of using the apparatus before replacement (time point at which the apparatus started to be used or time point at which the apparatus was selected) to the time point at which the replacement component is selected, from the server of the weather center, based on the position data already registered for PQ meter 100, and then, identify temperature and humidity data.

The manager terminal 200 may update the learning data based on the identified temperature and humidity data and the replacement component.

A person skilled in the art of the present disclosure will understand that various exemplary logic blocks, modules, processors, means, circuits, and algorithm steps described in connection with the disclosed embodiments may be implemented using electronic hardware, various forms of programs or design code (for convenience, referred to here as software), or a combination of both. To clearly explain this interchangeability between hardware and software, various exemplary components, blocks, modules, circuits, and steps have been generally described above in relation to their functions. Whether such functions are implemented as hardware or software depends on the design constraints imposed on a particular application and the overall system. A person skilled in the art of the present disclosure can implement the described functions in various ways for each specific application. However, such implementation choices should not be interpreted as falling outside the scope of the present disclosure.

The various embodiments presented herein may be implemented as a method, an apparatus, or an article of manufacture using standard programming and/or engineering techniques. The term “article of manufacture” includes any computer-readable storage device, carrier, or medium accessible by a computer program. For example, a computer-readable storage medium may include magnetic storage devices (e.g., hard disks, floppy disks, magnetic strips, etc.), optical disks (e.g., CDs, DVDs, etc.), smart cards, and flash memory devices (e.g., EEPROMs, cards, sticks, key drives, etc.), but is not limited thereto. Furthermore, various storage media presented herein include one or more devices and/or other machine-readable media for storing information.

It should be understood that the specific order or hierarchy of the steps in the presented processes is merely an example of an approach. Based on design priorities, the specific order or hierarchy of the steps in the processes may be rearranged within the scope of the present disclosure. The appended method claims provide elements of various steps in an exemplary order but do not imply a limitation to the specific order or hierarchy presented.

The descriptions of the presented embodiments are provided to enable any person skilled in the art of the present disclosure to utilize or implement the invention. Various modifications of these embodiments will be apparent to those skilled in the art, and the general principles defined herein may be applied to other embodiments without departing from the scope of the present disclosure. Therefore, the present disclosure should not be limited to the embodiments presented herein but should be interpreted within the broadest possible scope consistent with the principles and novel features disclosed.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

What is claimed is:

1. A system including a power quality (PQ) meter, comprising:
the PQ meter; and
a manager terminal,
wherein the PQ meter includes:
a first signal generation circuit that includes a current transformer and a voltage transformer, which are connected to both ends of an alternate current (AC) wire disposed at one end of AC/DC power converter, and applies first signals in connection with AC current and AC voltage, respectively, from the current transformer and voltage transformer; 9
a second signal generation circuit that is connected to a DC wire disposed at the other end of the AC/DC power converter and applies second signals in connection with DC voltage and DC current, respectively, from the DC wire;
a communication circuit; and
a control circuit that generates PQ data based on applied signal when at least one among the first and second signals is applied, and then transports the PQ data to the manager terminal at a constant cycle,
wherein the number of the current transformers and the number of the voltage transformers correspond to the number of phases on the AC wire, and
the PQ data include at least one data among a relationship between voltage bandwidth and power quality, supply voltage deviation, ripple and high frequency noise, voltage rise and droop, voltage supply cut-off, rapid change in voltage, voltage surge and voltage imbalance.

2. The system according to claim 1, wherein the PQ meter includes a display, the control circuit identifies areas of the display, on which PQ data for AC and PQ data for DC are outputted, respectively; and, when PQ is not included in a standard range, outputs the PQ data on a matching area based on the PQ data through the display.

3. The system according to claim 1, wherein the first signal generation circuit includes:
an AC voltage sensor;
an AC current sensor; and
a plurality of first analog front ends (AFEs) connected to the AC voltage sensor and the AC current sensor, respectively;
the second signal generation circuit includes:
a DC voltage sensor;
a DC current sensor; and
a plurality of second AFEs connected to the DC voltage sensor and the DC current sensor, respectively.

4. The system according to claim 3, wherein the PQ meter includes at least one analog-to-digital converter (ADC),
wherein, when one ADC is used, it receives analog signals from the first AFE and the second AFE; and, when several ADCs are used, they receive analog signals from the first AFE and the second AFE, respectively.

5. The system according to claim 4, wherein the ADC is controlled by the control circuit or an external ADC control circuit.

6. The system according to claim 1, wherein the first signal generation circuit applies the first signal from a grounding wire when the circuit is connected to the grounding wire of a grounded voltage transformer (GVT).

7. The system according to claim 1, wherein the manager terminal includes:
a processor;
a memory; and
a communication module,
wherein the memory includes commands for the processor to execute the following steps, and the steps include:
receiving the PQ data from the PQ meter;
determining power supply based on the PQ data; and
outputting alarm for supply limitation based on the determined result.

8. The system according to claim 7, wherein the system includes a storage apparatus, and the storage apparatus include:
a first switch located on the DC wire;
a charge wire, which is connected to a point between the AC/DC power converter and the first switch at one end of the charge wire on the DC wire, and includes a second switch;
a battery connected to the other end of the charge wire to store power;
a second communication circuit; and
a second control circuit to control operation of the second switch,
wherein the second signal generation circuit is connected between the AC/DC power converter and the above point,
wherein the steps include:
when a power quality (PQ) is determined to be less than a critical level in the case of determining the supply of power, transporting a control command to the storage apparatus to open the first switch while closing the second switch, so as to charge the battery; and
when the PQ is not less than the critical level and is maintained this state over a predetermined time, transporting another control command to the storage apparatus to close the first switch while opening the second switch based on the PQ data, so as to apply the supply of power.

9. The system according to claim 8, wherein, based on learning data including at least one among data for PQ change per time, data for wire replacement history, data for specification of power converter, data for specification of switch, and data for operational history of switch, the memory includes an artificial intelligence (AI) model that is trained to determine the number of switch operations, the expected time point at which PQ is changed to less than the critical level in regard to data for PQ, and the component causing deterioration in PQ among the power converter, wires and switches, and
wherein the steps include:
inputting the cumulative number of operations of each of the first switch and the second switch, and PQ data into the AI model in order to determine power supply;
determining a first time point to operate the switch within a first time as a predetermined time, based on the output of AI model; and
outputting alarm for the first time point when the first time point is determined.

10. The system according to claim 9, wherein the steps include:
in the case of determining the first time point, when the first time point is determined, determining a second time point at which PQ is not less than the critical level within a second time as another predetermined time longer than the first time, based on the output of AI model;
when the second time point is not determined, identifying at least one aged component among the AC/DC power converter, the DC wire, the AC wire, the first switch and the second switch data, based on the output of AI model; and
when the aged component is identified, outputting a request for replacing the aged component and, when the aged component is not identified, outputting a request for entire inspection of power facilities.
